(19) United States
(12) Patent Application Publication
(10) Pub. No.: US 2013/0327398 A1
(43) Pub. Date: Dec. 12, 2013

(54) Thin-Film Photovoltaic Devices and Methods of Manufacture

(71) Applicants: Ramesh Dhere, Lakewood, CO (US); Joel Duenow, Golden, CO (US); Timothy A. Gessert, Conifer, CO (US)

(72) Inventors: Ramesh Dhere, Lakewood, CO (US); Joel Duenow, Golden, CO (US); Timothy A. Gessert, Conifer, CO (US)

(73) Assignee: ALLIANCE FOR SUSTAINABLE ENERGY, LLC, Golden, CO (US)

(21) Appl. No.: 14/001,607

(22) PCT Filed: Feb. 27, 2012
(86) PCT No.: PCT/US12/26829

§ 371 Date: Aug. 26, 2013

Related U.S. Application Data
(60) Provisional application No. 61/447,304, filed on Feb. 28, 2011.

(51) Int. Cl. H01L 31/073

(52) U.S. Cl. CPC H01L 31/073
USPC 136/256; 438/93; 438/95

(57) ABSTRACT

Improved thin-film photovoltaic devices and methods of manufacturing such devices are described. Embodiments include a substrate-configured thin-film PV device (200) having a photo-absorbing semiconductor layer (230) and a window layer (240). Embodiments include devices having a CdTe photo-absorbing semiconductor layer, a CdS or CdS:In window layer, and an n-p junction residing at or proximate an interface of the photo-absorbing semiconductor and window layers. Variations include methods of manufacture wherein i) O₂ is excluded from an ambient environment during deposition of the CdTe layer (102), ii) O₂ is included in an ambient environment during CdCl₂ treatment (103), iii) O₂ is included in an ambient environment during deposition of a CdS or CdS:In layer (104), or iv) a medium-temperature anneal (MTA) having an anneal temperature of 300° C. or less is performed (105) after deposition of the CdS layer.

### CROSS-REFERENCE TO RELATED APPLICATIONS

This application claims the benefit of U.S. Provisional Application No. 61/447,304 filed Feb. 28, 2011, which is incorporated herein by reference in its entirety.

### CONTRACTUAL ORIGIN

The United States Government has rights in this invention under Contract No. DE-AC36-080028308 between the United States Department of Energy and the Alliance for Sustainable Energy, LLC, the manager and operator of the National Renewable Energy Laboratory.

### BACKGROUND

Commercial prior art CdTe thin-Elm photovoltaic (PV) modules are generally manufactured in a “superstate” configuration. In the superstrate design, light enters the device through a transparent material (typically glass) that is used both to support the thin-film layers during deposition, and to provide a transparent front seal during deployment. Advantages to the superstrate design include permitting relatively easy access to a device back surface. Ready access to the back surface facilitates providing electrical contact at the back surface.

Conversely, in substrate-configured PV devices, thin-film layers are deposited onto materials that form the back or bottom side of the device. The back or bottom sides typically do not need to admit light, and therefore can be opaque. The substrate material typically, but not necessarily, comprises metal, high-temperature polymer, or ceramic material. Advantages of substrate-configured thin-film PV devices include high power to mass ratio, a thin-film PV module that is relatively flexible, and manufacture by relatively low-cost methods such as roll-to-roll processing.

Substrate-configured cadmium telluride (CdTe) thin-film photovoltaic devices are typically inexpensive to produce and achieve desirable power to mass, but actual device efficiency falls short of predicted efficiency. Efficiencies of substrate-configured CdTe PV devices should be higher than superstrate-configured devices because optical losses can be reduced. However, efficiencies of prior art substrate-configured CdTe devices, typically about 6-8%, are significantly lower than superstrate designs, which have achieved about 17% efficiency.

Variations of prior art devices are manufactured without incorporation of oxygen into the CdTe layer, a method of manufacture offering advantages under some conditions. However, where oxygen is largely absent from the CdTe layer, device performance tends to suffer.

Deposition of CdTe under oxygen depleted conditions is thought to result in relatively abundant Te vacancy defects (V_{Te}), which can be problematic at a CdTe/CdS interface. It is thought that V_{Te} facilitates diffusion of S into the CdTe layer, which results in a junction residing too deep in the CdTe layer for optimal performance. Moreover, V_{Te} are thought to serve as recombination centers for electrons, which further diminishes device performance. Electrons are minority carriers in the CdTe layer.

Prior art substrate-configured PV devices with oxygen depleted CdTe layers typically suffer from relatively low open-circuit voltage (V_{OC}) and low fill factor (FF). Where the CdTe layer is deposited under oxygen depleted conditions, the resulting prior art CdTe PV device has a V_{OC} of approximately 700 mV or less, and a FF of about 30% or less, performance that falls short of superstrate-configured CdTe thin-film PV devices. Performing a CdCl₂ heat treatment in the presence of oxygen results in modest increase in device performance where the CdTe layer was deposited in an oxygen depleted ambient.

### BRIEF DESCRIPTION OF THE DRAWINGS

Exemplary embodiments are illustrated in referenced figures of the drawings.

It is intended that the embodiments and figures disclosed herein are to be considered illustrative rather than limiting.

FIG. 1 illustrates a flow chart illustrating a first method of manufacturing an improved thin-film PV device.

FIG. 2 illustrates a cross section view of an improved thin-film PV device.

FIG. 3 illustrates a graph showing device open circuit voltage (V_{OC}) as a function of anneal temperature for variations of improved thin-film PV devices.

FIG. 4 illustrates a graph showing device short circuit current density (J_{SC}) as a function of anneal temperature for variations of improved thin-film PV devices.

FIG. 5 illustrates a graph showing device fill factor (FF) as a function of anneal temperature for variations of improved thin-film PV devices.

FIG. 6 illustrates a graph showing device efficiency as a function of anneal temperature for variations of improved thin-film PV devices.

FIG. 7 illustrates a graph showing current vs voltage for an improved thin-film PV device.

### DETAILED DESCRIPTION

Embodiments of improved thin-film PV devices include substrate-configured thin-film PV devices comprising photo-absorbing semiconductor layers and window layers. Embodiments include devices comprising a CdTe photo-absorbing semiconductor layer, a cadmium sulfide (CdS) or indium-doped CdS (CdS:In) window layer, and an n-p junction residing at or proximate an interface of the CdTe and CdS or CdS:In layers. Variations include methods of manufacture wherein i) O₂ is excluded from an ambient environment during deposition of the CdTe layer, ii) O₂ is included in an ambient environment during CdCl₂ treatment, iii) O₂ is included in an ambient environment during deposition of CdS or CdS:In, or iv) a medium-temperature anneal (MTA) having an anneal temperature of 300° C. or less is performed after deposition of CdS or CdS:In.

Photo-absorbing semiconductor layers include semiconductor material selected from the group consisting of Group II-VI semiconductors; Group I-III-VI semiconductors; Group I-II-IV-VI semiconductors; selected kesterites; and selected chalcopyrites. Performance for substrate-configured CdTe PV devices can be improved by execution of one or more of operations 1-4, below:
1) Following oxygen depleted deposition of the CdTe layer, but prior to deposition of the CdS layer, a CdCl₂ heat treatment is performed in the presence of oxygen, which generally leads to improvement in device performance;
2) Oxygen is incorporated during deposition of the CdS layer, which is thought to generate a CdS:O layer. Oxygen incorporation during deposition of the CdS layer can be performed after including oxygen during the CdCl₂ heat treatment, a combination that improves device performance over that achieved by either of operation 1 or 2 alone;
3) Indium is introduced at the CdS/CdTe interface. The resulting CdS:In enhances CdTe device performance. CdS:In is typically, but not necessarily, deposited by RF magnetron sputter deposition in an ambient containing O₂, which is thought to result in CdS:O:In deposition. Embodiments comprise other methods for depositing CdS:In, including but not limited to, evaporation and aqueous chemical deposition.
4) After including oxygen during application of CdS or CdS:In, subjecting the device to an MTA further improves device performance. MTA is generally performed at an oven temperature of about 160° C. to 300° C., and typically, but not necessarily, in an O₂ depleted ambient. The O₂ depleted ambient typically consists essentially of a relatively inert gas. Relatively inert gases include, but are not limited to, nitrogen (N₂), noble gases including helium (He), neon (Ne), argon (Ar), krypton (Kr), and xenon (Xe), and fluorinated hydrocarbons including CHF₃, and C₂H₂F₄. MTA can lead to significant improvement in device performance. In some embodiments, MTA is performed in an ambient that includes significant levels of O₂ in addition to a relatively inert gas. Combinations of the operations described above typically improve device performance greater than any of the operations performed separately.

Exemplary embodiments of substrate-configured CdTe PV devices manufactured with CdTe deposited in an oxygen depleted ambient, and also manufactured using some or all of operations 1-4 above exhibit efficiencies as high as 10.97% and FF values of approximately 60.5%. Moreover, V_{OC} as high as 863 mV has been detected, a value that surpasses V_{OC} for typical superstrate-configured CdTe thin-film photovoltaic devices.

It is thought that the presence of oxygen in the CdTe layer improves device performance because Te vacancies in the CdTe layer (V_{Te}) become occupied by oxygen, resulting in an oxygen on Te substitution (O_{Te}). It is furthermore thought that oxygen can inhabit the CdTe layer interstitially or at grain boundaries.

O_{Te}s are thought to enhance device performance because O_{Te}s may be less efficient recombination centers compared to V_{Te}. Moreover, O_{Te}s are thought to impede S infiltration of the CdTe layer such that a preferred junction depth is achieved. The MTA is also thought to enhance further O_{Te} and to impede infiltration of S into the CdTe layer. In some embodiments, O_{Te} defects produced at medium temperatures is thought to yield advantageous defect pairs with Cu. For example, it is thought that interstitial Cu (Cuᵢ) can form a Cuᵢ—O_{Te} defect pair in the CdTe layer. The advantageous defect pairs can be donors, which can enhance the quality of the n-type region of the buried quasi-homojunction.

It is thought that the presence of In near the CdTe/CdS interface that results from CdS:In deposition can enhance the n-type character of CdS, and can also impart n-type character to CdTe. This is thought to result from substitution of In for Cd in both CdS and CdTe. Moreover, where a CdSTe interdiffused layer forms as a result of MTA, introducing In at the CdTe/CdS interface is thought to cause interdiffusion of In as well, leading to enhancement of n-type character of the In-doped CdSTe. The presence of indium may contribute to the formation of a quasi-homojunction between the n-type enhanced In-doped CdSTe layer and the p-type CdTe layer. The junction, therefore, is within the structurally-compatible volume of CdSTe and CdTe rather than at the metallurgical junction of the CdS (CdS:In) and CdTe. It is thought that this can reduce the number of interface defects present, and thus reduce minority carrier recombination. V_{OC}, and device efficiency are thus enhanced.

For the buried quasi-homojunction, it is thought that the electrical junction is located between structurally compatible Te-rich n-type CdSTe, which exhibits cubic lattice structure formed by interdiffusion of CdS and CdTe, and p-type CdTe, which also exhibits cubic lattice structure. Because the electrical junction is not located at the metallurgical junction of the CdS (having hexagonal lattice structure) and CdTe (having cubic lattice structure), where many interfacial defects may be present, the quasi-homojunction may be of superior quality by virtue of its location in a region with fewer defects.

### Terminology

The terms and phrases as indicated in quotation marks (“ ”) in this section are intended to have the meaning ascribed to them in this Terminology section applied to them throughout this document, including in the claims, unless clearly indicated otherwise in context. Further, as applicable, the stated definitions are to apply, regardless of the word or phrase's case, to the singular and plural variations of the defined word or phrase.

The term “or” as used in this specification and the appended claims is not meant to be exclusive; rather the term is inclusive, meaning either or both.

References in the specification to “one embodiment”, “an embodiment”, “another embodiment, “a preferred embodiment”, “an alternative embodiment”, “one variation”, “a variation” and similar phrases mean that a particular feature, structure, or characteristic described in connection with the embodiment or variation, is included in at least an embodiment or variation of the invention. The phrase “in one embodiment”, “in one variation” or similar phrases, as used in various places in the specification, are not necessarily meant to refer to the same embodiment or the same variation.

The term “couple” or “coupled” as used in this specification and appended claims refers to an indirect or direct physical connection between the identified elements, components, or objects. Often the manner of the coupling will be related specifically to the manner in which the two coupled elements interact.

The term “directly coupled” or “coupled directly,” as used in this specification and appended claims, refers to a physical connection between identified elements, components, or objects, in which no other element, component, or object resides between those identified as being directly coupled.

The term “approximately,” as used in this specification and appended claims, refers to plus or minus 5% of the value given.

The term “about,” as used in this specification and appended claims, refers to plus or minus 20% of the value given.

The terms “generally” and “substantially,” as used in this specification and appended claims, mean mostly, or for the most part.

Directional or relational terms such as “top,” bottom,” “front,” “back,” “above,” and “below,” as used in this specification and appended claims, refer to relative positions of identified elements, components, or objects, in a PV device designed and adapted to have light enter through a top of the device. Top is equivalent to front, and bottom is equivalent to back. Accordingly, a front contact resides at or proximate a top of the device, and a back contact resides at or proximate a bottom of the device. Similarly, a superstrate resides at or proximate a device top, and a substrate resides at or proximate a bottom of the device.

References to % O₂ refer to a proportion of total gas pressure due to O₂. For example, where a deposition chamber ambient is at a pressure of 16 torr and is 4% O₂, the partial pressure of O₂ in the chamber is 0.64 torr. Similarly, where a deposition chamber ambient consists of 300 torr Argon and 10 torr O₂, the ambient is 3.23% O₂.

The terms “ambient,” ambient environment,” and similar terms, refer to space immediately surrounding treatment or processing of thin-film PV devices, or components thereof. The space typically resides within an instrument, oven, chamber, or similar cavity, wherein the treatment or processing takes place. Conditions within the space, such as but not limited to O₂ content or abundance of other gas, are typically specified where reference to “ambient” is made.

The term “window layer,” as used in this specification and appended claims, refers to a layer of semiconductor material having a band gap at least 0.5 eV higher than a photo-absorbing semiconductor material residing below the window layer in a PV device. The semiconductor material of the window layer is of a different type than the photo-absorbing semiconductor. For example, where the photo-absorbing semiconductor material is p-type, the adjacent window layer is n-type.

The term “photo-absorbing semiconductor layer,” as used in this specification and appended claims, refers to a layer of semiconductor material that absorbs optical radiation to produce electron-hole pairs. These electron and hole charge carriers can then be collected through the assistance of the electric field formed between the n-type and p-type regions of the photovoltaic device.

The terms “group semiconductor” and “group I-III-VI semiconductor material,” as used in this specification and appended claims, refer to semiconductor material consisting of a combination of a group I element, a group III element, and a group VI element. The combination can include atoms bound covalently, through ionic attraction, or hybrids thereof. The combination can further include crystalline, polycrystalline, or amorphous arrangements, or amalgamations thereof. Group I elements include lithium (Li), sodium (Na), potassium (K), rubidium (Rb), cesium (Cs), francium (Fr), Copper (Cu), silver, (Ag), and gold (Au). Group III elements include scandium (Sc), yttrium (Y), lanthanum (La), boron (B), Aluminum (Al), gallium (Ga), Indium (In), and thallium (Th). Group VI elements include chromium (Cr), molybdenum (Mo), tungsten (W), uranium (U), oxygen (O), sulfur (S), selenium (Se), tellurium (Te), and polonium (Po).

The terms “group II-VI semiconductor” and “group II-VI semiconductor material,” as used in this specification and appended claims, refer to semiconductor material consisting of a combination of a group II element and a group VI element. The combination can include atoms bound covalently, through ionic attraction, or hybrids thereof. The combination can further include crystalline, polycrystalline, or amorphous arrangements, or amalgamations thereof. Group H elements include beryllium (Be), magnesium Mg), calcium (Ca), strontium (Sr), barium (Ba), radium (Ra), zinc (Zn), and mercury (Hg).

The terms “group I-II-IV-VI semiconductor” and “group I-II-IV-VI semiconductor material,” as used in this specification and appended claims, refer to semiconductor material consisting of a combination of a group I element, a group H element, a group IV element, and a group VI element. The combination can include atoms bound covalently, through ionic attraction, or hybrids thereof. The combination can further include crystalline, polycrystalline, or amorphous arrangements, or amalgamations thereof. Group IV elements include titanium (Ti), zirconium (Zr), hafnium Hf), thorium (Th), carbon (C), silicon (Si), germanium (Ge), tin (Sn), and lead (Pb).

The term “selected kesterites,” as used in this specification and appended claims, refers to Cu₂ZnSnS₄, Cu₂ZnSnSe₄, and Cu₂ZnSn(SeS)₄.

The term “selected chalcopyrites,” as used in this specification and appended claims, refers to: CuInGaSe₂; CuInGaS₂; CuInGa(SeS)₂; CuInSe₂; CuInS₂; CuIn(SeS)₂; CuGaSe₂; CuGaS₂; and CuGa(SeS)₂.

The terms “low pressure deposition,” and “low pressure deposition technique,” as used in this specification and appended claims, refer to thin-film deposition performed at ambient pressures below 375 torr. Low pressure deposition includes, but is not limited to, physical vapor deposition (PVD), sputtering, close-spaced sublimation (CSS), chemical vapor deposition (CVD), evaporative deposition, and atomic layer deposition (ALD). Close-spaced sublimation is sometimes referred to as closed-space sublimation or close-space sublimation. Gas-phase deposition of thin-films at ambient pressures above 375 torr can be performed, but are not considered low pressure deposition techniques.

Unless specified otherwise, where a temperature or temperature range is described, the temperature or temperature range refers to temperature of the oven, chamber, or similar instrument or cavity, rather than the temperature of a PV device or component thereof contained within the oven, chamber, or similar instrument or cavity. Where a substrate temperature, source plate temperature, or other object temperature is specified, the specified temperature is for the substrate, source plate, or other object itself, rather than for the oven, chamber, or cavity within which the substrate, source plate, or other object resides.

### A First Method of Manufacturing an Improved Thin-Film PV Device

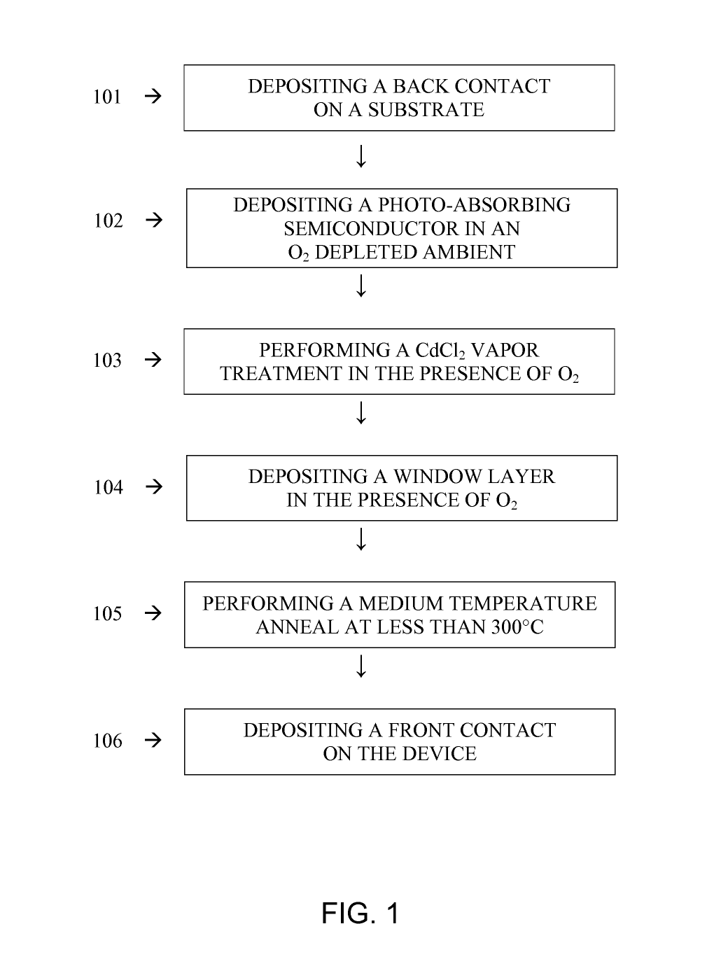

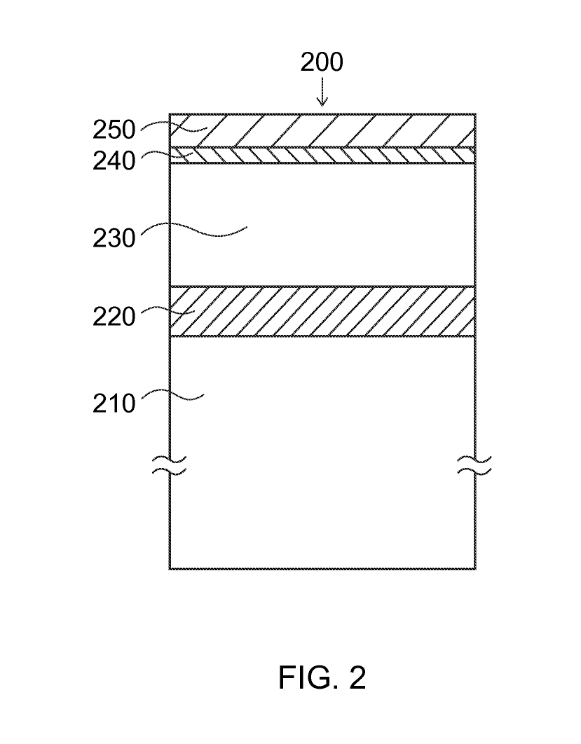

A first method of manufacturing an improved thin-film PV device is illustrated in FIG. 1, and results in a first embodiment improved thin-film device 200, illustrated in FIG. 2. In a first operation 101 of the first method, a back contact 220 is deposited on a substrate 210. The first method substrate is typically Corning 7059 glass having a thickness of 0.8 mm. Embodiments of substrates can be opaque, transparent, or translucent, and can be flexible or rigid. Variations of substrates include, but are not limited to, metals and metal alloys, metal foil, metal alloy foil, flexible glass, rigid glass, and polymeric substrates. Polymeric substrates typically comprise high-temperature polymers that can withstand a temperature of 400° C. without substantially melting or degrading. Examples of high-temperature polymers include, but are not limited to, polyimides.

The first embodiment back contact 220 comprises a metal back contact layer including a layer of Cr approximately 50 nm thick and a layer of Mo approximately 800 nm thick. In the first operation 101 of the first method, the Cr and Mo layers are applied to the glass substrate 210 by direct current sputtering at room temperature, using a power of approximately 1050 watt (W) and greater than 99.99% Ar sputtering gas throttled to 14 and 10 millitorr (mtorr), respectively. Other back contact layers include other metals, including non-diffusive metals.

The first embodiment back contact 220 further comprises a back contact interface layer consisting essentially of CuₓTe about 10 nm thick. Accordingly, the first operation 101 of the first method comprises depositing the CuₓTe layer on the metal back contact layer by radio frequency (RF) magnetron sputtering at room temperature in 10 mtorr of 99.99% or greater Ar, at 19 W power. Variations of back contact interface layers include, but are not limited to Cu-doped ZnTe, MoO₃, SbTe₃, MoSe₂, MoTe₂, and CuₓTe. The metal back contact bilayer and back contact interface layer are referred to collectively as the back contact or back contact layers.

A second operation 102 comprises depositing a layer of photo-absorbing semiconductor material 230 on the back contact 220 by low pressure deposition. The photo-absorbing semiconductor material of the first method is typically CdTe. The CdTe layer is approximately 4 μm thick and is deposited by CSS from a CdTe source plate, at a substrate temperature of 450-600° C. and a source temperature of 660-670° C. The oxygen depleted ambient in the deposition chamber consists essentially of He at 16 torr, with 0.5% or less O₂ (80 mtorr). Variations include an oxygen depleted ambient that is often less than 1.0% O₂ (160 mtorr for 1.0% O₂ in He at 16 torr), still more often less than 2.0% O₂ (320 mtorr for 2.0% O₂ in He at 16 torr), and most often less than 4.0% O₂ (640 mtorr for 4.0% O₂ in He at 16 torr). Conversely, prior art CdTe deposition by CSS is typically performed with a deposition chamber ambient consisting essentially of 15 torr He and 1 torr O₂ (6.25% O₂).

A variant of the second operation comprises depositing a 3-4 μm thick CdTe layer by evaporative deposition, wherein an ambient of less than 2×10⁻⁶ torr is established in a vacuum chamber prior to commencing CdTe deposition. The substrate and back contact are maintained at 400° C. during evaporative deposition, and a CdTe powder source is heated to 670° C. in an alumina crucible, whereupon CdTe evaporates from the crucible and deposits on the back contact. Although no process gas is added to the vacuum chamber, at a pressure of less than 2×10⁻⁶ torr, the evaporative deposition ambient comprises very low O₂ pressure. O₂ pressure during evaporative deposition is often less than 4×10⁻⁷ torr, more often less than 2×10⁻⁶ torr, and most often less than 1×10⁻³ torr.

In some embodiments, the photo-absorbing semiconductor material is selected from the group consisting of: group II-VI semiconductors; group I-III-VI semiconductors; group I-II-IV-VI semiconductors; selected kesterites; and selected chalcopyrites.

Upon deposition of the CdTe layer 230, the back contact 220 is in ohmic contact to the CdTe layer. The ohmic contact is a non-rectifying junction and does not substantially disturb the p-type character of the CdTe. In some embodiments, the back contact enhances the p-type character of the CdTe.

A third operation 103 comprises CdCl₂ vapor treatment by a low pressure technique in an ambient containing O₂. The third operation low pressure technique of the first method is CSS with an ambient consisting essentially of 80 torr O₂ and 320 torr He (20% O₂ in He), at a source and substrate temperature of 400° C. Variations include CdCl₂ vapor treatment in ambients often including at least 10% O₂, more often including at least 5% O₂, still more often including at least 1% O₂, and most often including at least 0.5% O₂.

A fourth operation 104 comprises applying a window layer 240 by low pressure deposition in an ambient containing O₂. The window layer deposition of the fourth operation 104 comprises RF magnetron sputtering of CdS at room temperature and 50 W power using a 15 mtorr ambient including 2.0% O₂ in Ar. The resulting CdS window layer 240 is approximately 125 nm thick. It is understood that the CdS layer likely includes CdS:O because of the presence of O₂ during deposition. Variations include CdS deposition in ambients often including at least 4.0% O₂, more often including 2.0% to 4.0% O₂, still more often including at least 1% O₂, and most often including at least 0.5% O₂.

In some embodiments, the window layer is deposited by gas-phase deposition at greater than 375 torr. Deposition of window layers by liquid coating processes is also contemplated. Examples of liquid coating processes include, but are not limited to, slot-die coating, spin-casting, drop-casting, dip-coating, knife coating (also known as doctor blading), spray-coating, ink-jet printing, screen printing, Mayer rod coating (also known as metering rod coating), Gravure coating, Flexo printing, and curtain coating.

A variant of the fourth operation comprises applying a window layer including CdS:In. CdS:In is deposited by RF magnetron sputtering at 60W power from a target comprising 0.5 mol % In₂S₃ in CdS. The sputtering is performed at room temperature in a 15 mtorr ambient including 3% O₂ in Ar. It is understood that the CdS:In layer likely includes CdS:O:In because of the presence of O₂ during deposition. Embodiments include CdS:In deposition in ambients often including at least 4.0% O₂, more often including 2.0% to 4.0% O₂, still more often including at least 1% O₂, and most often including at least 0.5% O₂.

A fifth operation 105 comprises a medium temperature anneal (MTA) performed in a 100 standard cubic centimeter per minute (sccm) flow of ≧99.99% He for 30 minutes at oven temperatures of 175° to 300° C. The MTA is performed at any point after deposition of the window layer.

A sixth operation 106 comprises applying a front contact 250 by reduced pressure deposition. The front contact 250 of the first embodiment is a bilayer comprising an intrinsic ZnO (i-ZnO) buffer layer approximately 100 nm thick and an Al-doped ZnO (ZnO:Al) transparent contact approximately 120 nm thick. The sixth operation 106 front contact deposition includes RF magnetron sputtering of the i-ZnO buffer layer at room temperature and 330 W power in an ambient consisting essentially of approximately 0.8% O₂ in Ar, throttled to 5 mtorr. The sixth operation 106 front contact deposition further includes RF magnetron sputtering of the ZnO:Al transparent contact at room temperature and 550 W power using a ≧99.99% Ar sputtering gas throttled to 5 mtorr. The ZnO:Al layer is deposited from a target consisting essentially of 2% by weight Al₂O₃ in ZnO.

In some embodiments, a metal grid is deposited on the front contact. Embodiments of metal grids consist essentially of a 50 nm layer of Ni and a 3 μm layer of Al deposited by electron beam evaporation at room temperature.

The first embodiment improved thin-film PV device 200 is substrate-configured and achieves a V_{OC} of approximately 863 mV at illumination of about 1 sun (1 kW/m²). FF of the first embodiment is approximately 58%. V_{OC}, FF, short-circuit current, short-circuit current density (J_{SC}, and efficiency are obtained using methods described in the following ASTM standards:

ASTM E948-2009, STANDARD TEST METHOD FOR ELECTRICAL PERFORMANCE OF PHOTOVOLTAIC CELLS USING REFERENCE CELLS UNDER SIMULATED SUNLIGHT (equivalent to IEC 60904-1); and

ASTM E1328-2005, STANDARD TERMINOLOGY RELATING TO PHOTOVOLTAIC SOLAR ENERGY CONVERSION (equivalent to IEC 61836).

Table I shows performance of embodiments of substrate-configured improved thin-film PV devices manufactured by variations of the first method described above. The devices represented in Table 1 comprise a back contact deposited on Corning 7059 glass substrate. The back contact comprises a metal back contact layer consisting essentially of Mo, and a 10 nm layer of CuₓTe. A photo-absorbing semiconductor layer comprising a 4 μm layer of CdTe deposited by CSS at 550° C. in the absence of O₂ is deposited on the back contact. CdCl₂ treatment of the CdTe layer is performed at 400° C. for 4 minutes in the presence of O₂, and a 125 nm window layer comprising CdS sputtered in the presence of O₂ is deposited on the CdTe layer. The effects on device performance of anneal temperature during MTA is shown in Table I. The MTA is performed for 30 minutes at various anneal temperatures from 175° to 275°. Device performance parameters in Table 1 are V_{OC}, FF, J_{SC}, and device efficiency.

TABLE I
Substrate-configured CdTe/CdS Thin-film PV Device
Performance After MTA At Various Anneal Temperatures

| | V_{OC} (mV) | J_{SC (mA/cm}²) | FF (%) | Efficiency (%) |
|---|---|---|---|---|
| No MTA | 741 | 16.3 | 41.5 | 5.00 |
| 175° C. | 823 | 18.9 | 45.8 | 7.12 |
| 200° C. | 850 | 20.2 | 49.3 | 8.44 |
| 225° C. | 863 | 20.8 | 53.9 | 9.68 |
| 250° C. | 857 | 21.3 | 55.2 | 10.07 |
| 275° C. | 849 | 20.5 | 52.9 | 9.20 |

All devices represented in Table 1 subjected to MTA show a V_{OC} of at least 820 mV. On the basis of FF, J_{SC}, and Efficiency, an anneal temperature of 250° C. (for an MTA interval of 30 minutes) appears optimal or near optimal for the substrate-configured CdTe thin-film PV devices tested.

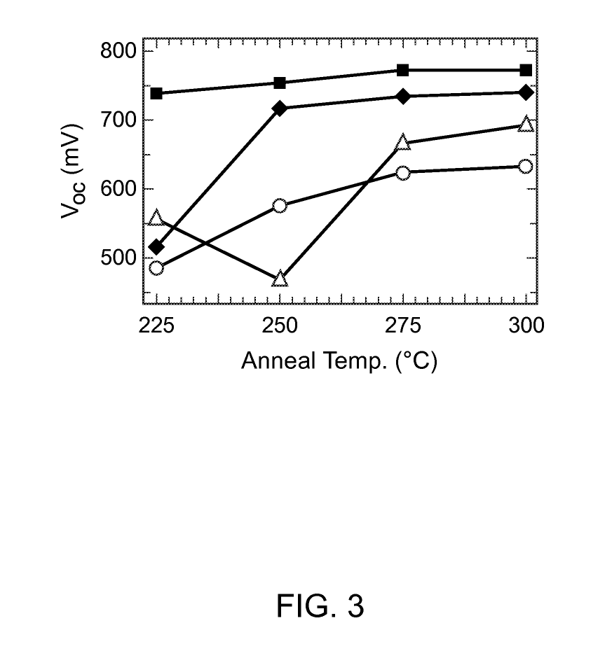

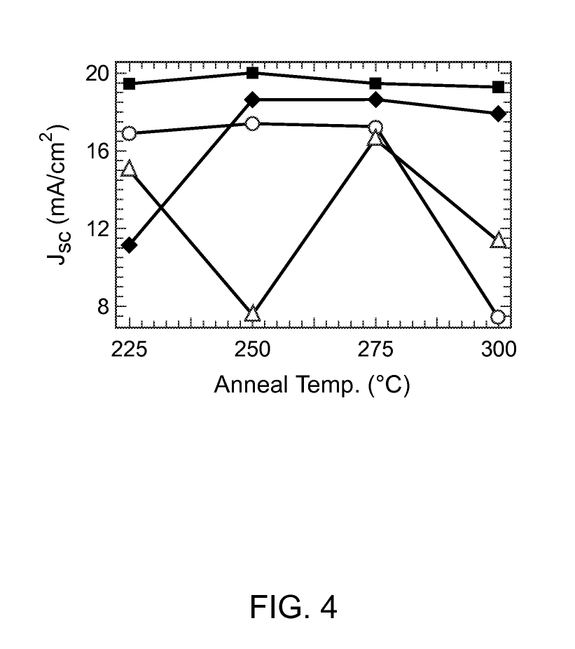

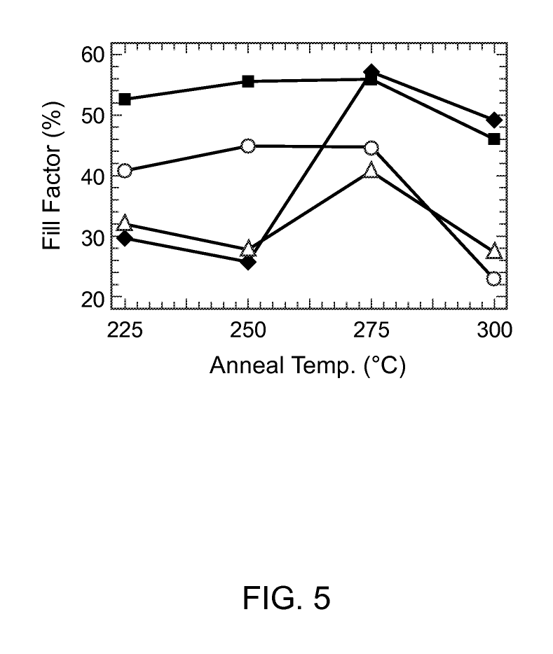

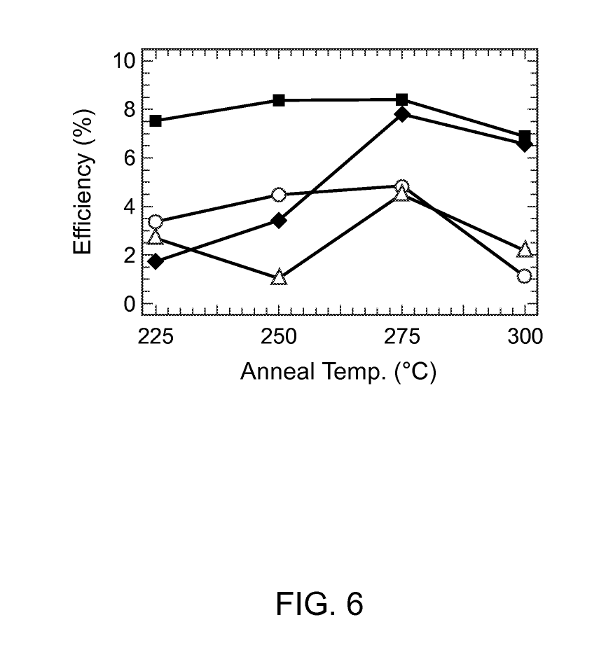

Effects on device performance of various anneal temperatures during MTA, using variations in methods of manufacture of substrate-configured CdTe/CdS thin-film PV devices, are illustrated in FIGS. 3-6. Device performance parameters are shown for methods of manufacture in which the presence or absence of O₂ during CdCl₂ treatment and during CdS deposition are varied. A legend FIGS. 3-6 is as follows:

Δ=O₂ absent during CdCl₂ treatment and absent during CdS deposition;

◯=O₂ present during CdCl₂ treatment and absent during CdS deposition;

♦═O₂ absent during CdCl₂ treatment and present during CdS deposition;

▪—O₂ present during CdCl₂ treatment and present during CdS deposition.

V_{OC}, J_{SC}, FF, and device efficiency are shown as functions of anneal temperature in FIGS. 3, 4, 5, and 6, respectively. For all devices represented in FIGS. 3-6, a CdTe photo-absorbing semiconductor layer is deposited by CSS in the absence of ambient O₂. Collectively, FIGS. 3-6 indicate optimal device performance where O₂ is present during CdCl₂ treatment and during CdS deposition, and the temperature for MTA is in the range of 250° C.-275° C.

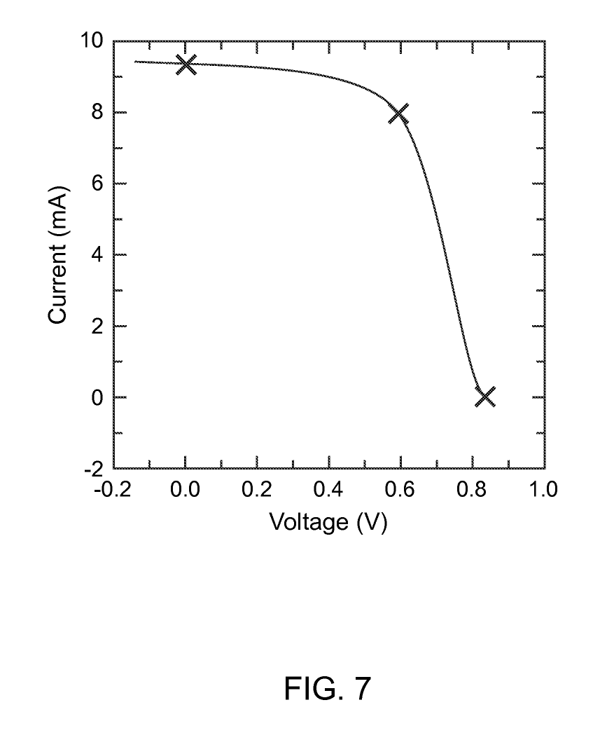

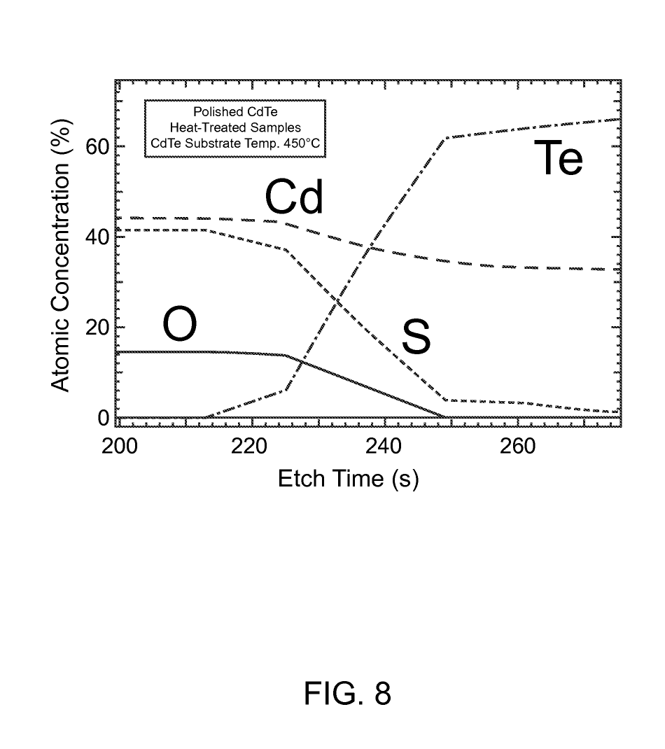

FIG. 7 illustrates device performance for a substrate-configured CdTe thin-film PV device manufactured by the first method. The device includes a CdS:In layer deposited according to the third operation variant of the first method. FIG. 7 shows current (mA) vs voltage (V) for a device having an illuminated area of 0.4301 cm². Irradiance is 1000 W/m² (1 sun) and device temperature is 24.8±0.5° C. The device exhibits the following performance metrics: V_{OC}=0.833 V; I_{SC}=9.355 mA; J_{SC}=21.75 mA/cm²; FF=60.5%; Efficiency=10.97%; Iₘₐₓ=7.969 mA; Vₘₐₓ=0.592 V; Pmax=4.7161 mW.

FIG. 8 illustrates atomic concentration of Cd, Te, S, and O, for a vacation of the first embodiment improved thin-film device manufactured by the first method described above, stopping after the fifth operation, wherein the anneal temperature during the MTA of the fifth operation is performed at 250° C. for 30 min. The CdCl₂ of the third operation treatment comprises CSS in an ambient consisting essentially of 80 torr O₂ and 320 torr He (20% O₂ in He), at a source and substrate temperature of 400° C. for 5 min. The window layer of the fourth operation is deposited by RF magnetron sputtering of a 125 nm thick CdS layer at room temperature and 50 W power using a 15 mtorr ambient including 2.0% O₂ in Ar.

Chemical composition at various levels in the device were measured by Auger

Electron Spectroscopy (AES). FIG. 8 shows atomic concentration as a function of depth into the first embodiment substrate-configured CdTe device. AES chemical composition measurements are performed as a function of time as the part of the sample to be measured was sputter-etched away. Thus, the chemical composition as a function of time corresponds to the chemical composition as a function of depth into the sample. The sample is measured from the top, so the CdS:O layer is encountered at lower etch times, which are plotted on the abscissa. At greater etch times, the CdS:O layer is completely etched away, revealing the CdTe layer beneath it.

FIG. 8 shows that the CdS:O layer includes approximately 14% oxygen at a maximum. As CdS:O gives way to CdTe, oxygen abundance diminishes as Te abundance increases, with equal amounts of Te and oxygen (about 12%) occurring at about 226 seconds etch time. Oxygen abundance is about 10% at approximately 230 seconds etch time and about 8% at approximately 235 seconds etch time.

The various embodiments and variations thereof, illustrated in the accompanying Figures and/or described above, are merely exemplary and are not meant to limit the scope of the invention. It is to be appreciated that numerous other variations of the invention have been contemplated, as would be obvious to one of ordinary skill in the art, given the benefit of this disclosure. All variations of the invention that read upon appended claims are intended and contemplated to be within the scope of the invention.

I claim:

1. A method of making a thin-film photovoltaic device comprising:
depositing a back contact on a substrate;
depositing a photo-absorbing semiconductor layer above the back contact;
depositing a window layer above the photo-absorbing semiconductor layer in an ambient comprising at least 0.5% O₂;
performing a medium temperature anneal of the photo-absorbing semiconductor layer and the window layer at an anneal temperature of 160° C. to 300° C.; and
depositing a front contact above the window layer.

2. The method of claim 1, wherein the photo-absorbing semiconductor layer is selected from the group consisting of group II-VI semiconductors, group semiconductors, group I-II-IV-VI semiconductors, selected kesterites, and selected chalcopyrites.

3. The method of claim 1, wherein the depositing the window layer is performed in an ambient comprising at least 2.0% O₂.

4. The method of claim 2, wherein the photo-absorbing semiconductor layer comprises a p-type semiconductor.

5. The method of claim 4, wherein the p-type semiconductor comprises a group II-VI semiconductor.

6. The method of claim 1, wherein the photo-absorbing semiconductor layer comprises cadmium telluride (CdTe).

7. The method of claim 3, wherein the window layer comprises a cadmium composition selected from the group consisting of cadmium sulfide (CdS) and indium-doped cadmium sulfide (CdS:In).

8. The method of claim 2, wherein the anneal temperature is 200° C. to 275° C.

9. The method of claim 2, wherein the anneal temperature is approximately 225° C. to approximately 250°.

10. The method of claim 2, further comprising performing a cadmium chloride (CdCl₂) treatment of the photo-absorbing semiconductor layer prior to depositing the window layer, wherein the step of performing the CdCl₂ treatment is executed in an ambient comprising at least 0.5% O₂.

11. The method of claim 6, wherein the step of depositing the photo-absorbing semiconductor layer is performed by a method selected from the group consisting of close-spaced sublimation (CSS) and evaporative deposition.

12. A substrate-configured thin-film photovoltaic device manufactured by the method of claim 7, wherein:
the step of depositing a photo-absorbing semiconductor layer above the back contact is performed in an ambient comprising less than 320 mtorr O₂; and
the device exhibits an open circuit voltage (V_{OC}) above 800 mV at an illumination of approximately 1 sun.

13. The substrate-configured thin-film photovoltaic device of claim 12, wherein the device further exhibits a fill factor of 45% or greater.

14. The substrate-configured thin-film photovoltaic device of claim 12, wherein the device further exhibits a V_{OC} above 850 mV and a fill factor of 50% or greater.

15. A thin-film photovoltaic device comprising:
a substrate or a superstrate;
a back contact;
a photo-absorbing semiconductor layer including CdTe;
a window layer including a cadmium composition selected from the group consisting of CdS and CdS:In; and
a front contact, wherein the device exhibits a V_{OC} above 820 mV and a fill factor of 50% or greater, at an illumination of approximately 1 sun.

16. The thin-film photovoltaic device of claim 15, wherein the thin-film photovoltaic device exhibits a V_{OC} of 860 mV or greater at an illumination of approximately 1 sun.

17. The thin-film photovoltaic device of claim 15, wherein the thin-film photovoltaic device exhibits efficiency equal to or greater than 10.0%.

18. A substrate-configured thin-film photovoltaic device comprising:
a substrate;
a back contact;
a photo-absorbing semiconductor layer comprising CdTe, the photo-absorbing semiconductor layer residing above the substrate;
a window layer comprising a cadmium composition selected from the group consisting of CdS and CdS:In; and
a front contact, wherein the device exhibits a V_{OC} above 700 mV and a fill factor of 45% or greater, at an illumination of approximately 1 sun.

19. The substrate-configured thin-film photovoltaic device according to claim 18, wherein the substrate-configured thin-film photovoltaic device exhibits a V_{OC} above 800 mV at an illumination of approximately 1 sun.

20. The substrate-configured thin-film photovoltaic device according to claim 19, wherein the substrate-configured thin-film photovoltaic device exhibits a V_{OC} above 850 mV and a fill factor of 50% or greater, at an illumination of approximately 1 sun.

21. The substrate-configured thin-film photovoltaic device of claim 18, wherein the substrate-configured thin-film photovoltaic device exhibits efficiency greater than 8%.

22. The substrate-configured thin-film photovoltaic device of claim 21, wherein the substrate-configured thin-film photovoltaic device exhibits efficiency greater than 9.5%.

23. A method of making a thin-film photovoltaic device comprising:
depositing a back contact on a substrate;
depositing a photo-absorbing semiconductor layer above the substrate in an ambient comprising less than 160 torr oxygen (O₂), the photo-absorbing semiconductor layer consisting essentially of CdTe;
depositing a window layer above the photo-absorbing semiconductor layer in an ambient comprising at least 2.0% O₂, the window layer consisting essentially of a cadmium composition selected from the group consisting of CdS and CdS:In;
performing a medium temperature anneal of the photo-absorbing semiconductor and window layers at an anneal temperature of 200° C. to 275° C.; and
depositing a front contact above the window layer.

24. The method of claim 23, further comprising performing a CdCl₂ treatment of the photo-absorbing semiconductor layer prior to depositing the window layer, wherein the step of performing the CdCl₂ treatment is executed in an ambient comprising at least 5.0% O₂.

25. A thin-film photovoltaic device manufactured by the method of claim 23, wherein the thin-film photovoltaic device exhibits a V_{OC} above 820 mV at an illumination of approximately 1 sun.
